(19) United States
(12) Patent Application Publication
(10) Pub. No.: US 2026/0271233 A1
(43) Pub. Date: Sep. 10, 2026

(54) HEAT DISSIPATION DEVICE AND SYSTEM

(71) Applicant: ZHENG-JEI LIN, Kaohsiung City (TW)

(72) Inventor: ZHENG-JEI LIN, Kaohsiung City (TW)

(21) Appl. No.: 19/241,812

(22) Filed: Jun. 18, 2025

(30) Foreign Application Priority Data
Mar. 10, 2025 (TW) 114108782

(51) Int. Cl. H05K 7/20

(52) U.S. Cl. CPC H05K 7/20327; H05K 7/20318

(57) ABSTRACT

A heat dissipation device includes a main body having a top side, a bottom side, a first penetration portion passing through the main body and forming a penetration space; a valve port on the main body; a first through hole on the top side; a second through hole on the bottom side; and a flow guiding device including: a box body defining a flow guiding space and including: an input hole and an output hole; a motor in the box body; and a rotor in the flow guiding space and connected to the motor; a first flow guide plate on the top side and forming a first flow guiding channel; a second flow guide plate on the bottom side and forming a second flow guiding channel; and a heat exchange plate disposed on one side of the first flow guide plate opposite to the main body.

### BACKGROUND OF THE DISCLOSURE

### 1. Field of the Disclosure

The present disclosure relates to heat dissipation devices, and more particularly, to a heat dissipation device for dissipating heat from a heat source of an electronic device.

### 2. Description of the Related Art

Operation of electronic device involves performance of high-speed computations and data processing. When executing such operations, the processor consumes electrical energy and generates heat. If the generated heat continuously accumulates without timely dissipation, the electronic device activates an overheating protection mechanism to prevent damage, so as to reduce the processing speed of the processor, thereby leading to a reduction in the operational efficiency of the electronic device. Also, operation of the electronic device under a high temperature for an extended period may cause a reduction in the lifespan of the electronic components, damage to the components, or instability of the system.

To improve the aforementioned issues, conventional technologies provide a heat dissipation device having water cooling mechanism. However, use of water as the coolant may cause the aging of the pipes, which may result in fluid leakage. Since water is not a highly volatile substance, in contact with electronic components, water may cause failure or damage to the components, and potentially result in malfunctions of the system. Further, in conventional heat dissipation devices, the cooling process is mostly performed by allowing the coolant to flow naturally, which may lead to an inefficient heat dissipation performance. When electronic components operate at a high power, the heat dissipation rate is unable to keep up with the rate of the temperature rise, resulting in limitations on the performance of the electronic components. Therefore, it is desirable to provide a heat dissipation device capable of achieving a high liquid tightness, high safety, and improved heat dissipation efficiency.

### SUMMARY OF THE DISCLOSURE

The present disclosure aims at providing a heat dissipation device with a high liquid tightness, high safety, and improved heat dissipation efficiency.

For achieving the aforementioned objectives, the present disclosure provides a heat dissipation device, comprising:
a main body having a top side and a bottom side arranged opposite to the top side, the main body further comprising:
a first penetration portion passing through the main body to communicate two ends of the main body and form a penetration space;
a valve port formed on an end of the main body;
a first through hole formed on the top side and in communication with the valve port and the penetration space;
a second through hole formed on the bottom side and in communication with the penetration space;
a flow guiding device disposed in the penetration space, comprising:
   a box body defining a flow guiding space therein and comprising:
      an input hole formed on one side of the box body at a position corresponding to the first through hole and in communication with the flow guiding space; and
      an output hole formed on another side of the box body at a position corresponding to the second through hole and in communication with the flow guiding space;
   a motor disposed in the box body; and
   a rotor accommodated in the flow guiding space and rotatably connected to the motor, so as to drive a first fluid to flow from the input hole through the flow guiding space toward the output hole;
a first flow guide plate disposed on the top side of the main body, a first flow guiding channel formed on one side of the first flow guide plate opposite to the main body, and an end of the first flow guiding channel being in communication with the first through hole;
a second flow guide plate disposed on the bottom side of the main body, a second flow guiding channel formed on one side of the second flow guide plate in contact with the main body, the second flow guiding channel having an end in communication with the second through hole and another end in communication with another end of the first flow guiding channel, the first fluid being flowable in the second flow guiding channel to absorb heat and vaporize; and
a heat exchange plate disposed on one side of the first flow guide plate opposite to the main body to cover the first flow guiding channel, the first fluid being flowable in the first flow guiding channel and cooled to condense into a liquid state via the heat exchange plate.

In another embodiment, the present disclosure provides a heat dissipation system, comprising:
a heat dissipation device, comprising:
   a main body having a top side and a bottom side arranged opposite to the top side, the main body further comprising:
      a first penetration portion passing through the main body to communicate two ends of the main body and form a penetration space;
      a valve port formed on an end of the main body;
      a first through hole formed on the top side and in communication with the valve port and the penetration space;
      a second through hole formed on the bottom side and in communication with the penetration space;
   a flow guiding device disposed in the penetration space, comprising:
      a box body defining a flow guiding space therein and comprising:
         an input hole formed on one side of the box body at a position corresponding to the first through hole and in communication with the flow guiding space; and
         an output hole formed on another side of the box body at a position corresponding to the second through hole and in communication with the flow guiding space;
      a motor disposed in the box body; and
      a rotor accommodated in the flow guiding space and rotatably connected to the motor, so as to drive a first fluid to flow from the input hole through the flow guiding space toward the output hole;
   a first flow guide plate disposed on the top side of the main body, a first flow guiding channel formed on one side of the first flow guide plate opposite to the main body, and an end of the first flow guiding channel being in communication with the first through hole;
   a second flow guide plate disposed on the bottom side of the main body, a second flow guiding channel formed on one side of the second flow guide plate in contact with the main body, the second flow guiding channel having an end in communication with the second through hole and another end in communication with another end of the first flow guiding channel, the first fluid being flowable in the second flow guiding channel to absorb heat and vaporize; and
   a heat exchange plate disposed on one side of the first flow guide plate opposite to the main body to cover the first flow guiding channel, the first fluid being flowable in the first flow guiding channel and cooled to condense into a liquid state via the heat exchange plate; and
a heat exchange device, comprising:
   a first heat exchange box disposed on one side of the heat exchange plate opposite to the first flow guide plate, with a heat absorbing channel formed in the first exchange box;
   a pump in communication with an end of the heat absorbing channel; and
a second heat exchange box comprising a cooling channel therein, the cooling channel having an end connected to the pump and another end in communication with another end of the heat absorbing channel, allowing the pump to pressurize a second fluid, whereby the second fluid circulates within the heat absorbing channel and the cooling channel.

With such configuration, the present disclosure does not require a compressor for refrigerant compression; instead, by merely rotating the motor rotor having blades within the flow guiding space, the first fluid (e.g., the refrigerant) is propelled in a forward direction from the flow guiding space sequentially through the output hole and the second through hole into the second flow guiding channel, so as to absorb heat to vaporize first. Then, the vaporized refrigerant flows from the second flow guiding channel through the second penetration portion and a third through hole into the first flow guiding channel, where the refrigerant releases the heat to condense back to the liquid state. Finally, the condensed refrigerant flows sequentially from the first flow guiding channel through a fourth through hole and the first through hole, and returns back to the flow guiding space, forming a continuous circulation loop, thereby achieving a stable and efficient heat exchange operation with minimal energy consumption. Also, components of the main body are allowed to be assembled with an airtight structure, so as to provide an excellent sealing performance for the main body, thereby preventing shaking of the flow guiding device and ensuring the sealing tightness of the first fluid, avoiding leakage thereof outside the main body, and ensuring the safety of electronic device when disposed on the second flow guide plate, so as to prevent the electronic device from being short circuited or damaged. Furthermore, in the present disclosure, a heat exchange device is disposed on the heat exchange plate to further transfer heat from the heat exchange plate to a remote location, so as to prevent excessive heat accumulation at the position of the heat exchange plate, thereby ensuring that the first fluid flowing back to the flow guiding space has been adequately cooled, allowing the next round of circulation of heat absorption and vaporization followed by heat dissipation and condensation operations. In summary, the present disclosure is applied to cool high-power computer processors, thereby allowing the processors to operate at high power without performance degradation.

### BRIEF DESCRIPTION OF THE DRAWINGS

FIG. 1A is an exploded view illustrating the structural features of the heat dissipation device in accordance with an embodiment of the present disclosure.

FIG. 1B is an exploded view illustrating the structural features of the flow guiding device in accordance with an embodiment of the present disclosure.

FIG. 1C is an exploded view illustrating the structural features of the heat dissipation device in accordance with an embodiment of the present disclosure.

FIG. 2A is an exploded view illustrating the structural features of the heat dissipation system in accordance with an embodiment of the present disclosure.

FIG. 2B is an exploded view illustrating the structural features of the heat exchange device in accordance with an embodiment of the present disclosure.

FIG. 3 is a schematic view illustrating the heat dissipation and condensation circulation.

### DETAILED DESCRIPTION OF THE DISCLOSURE

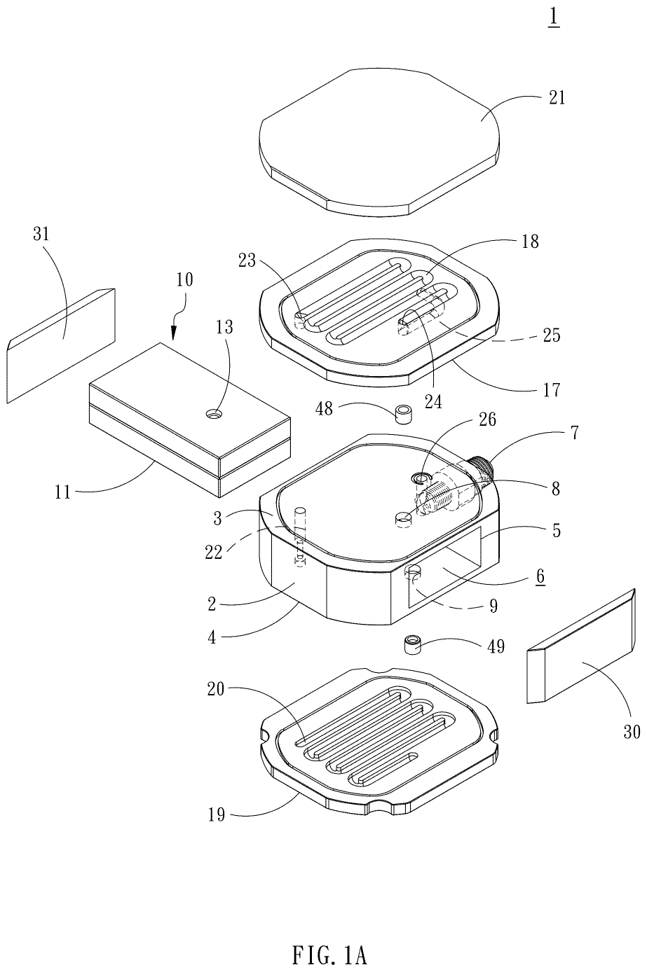

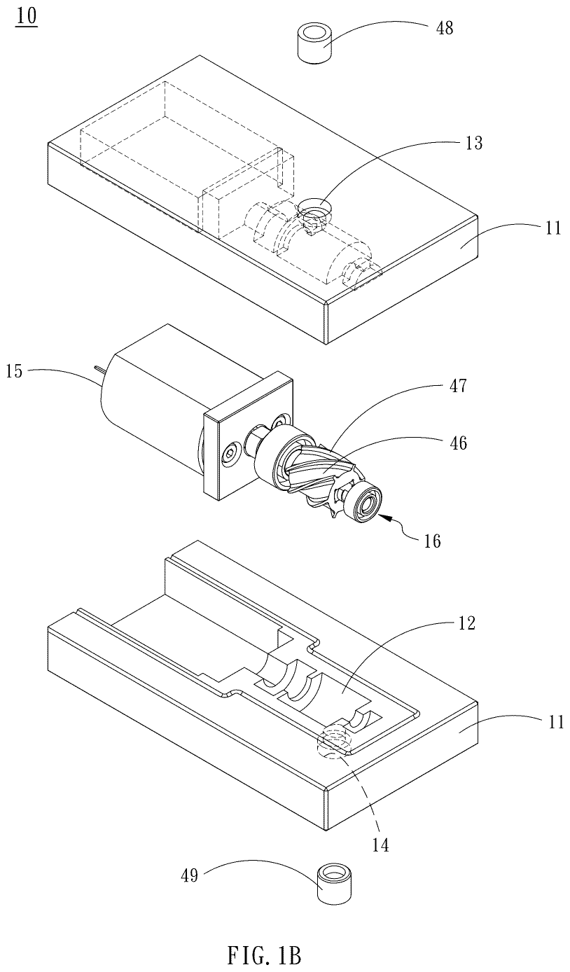

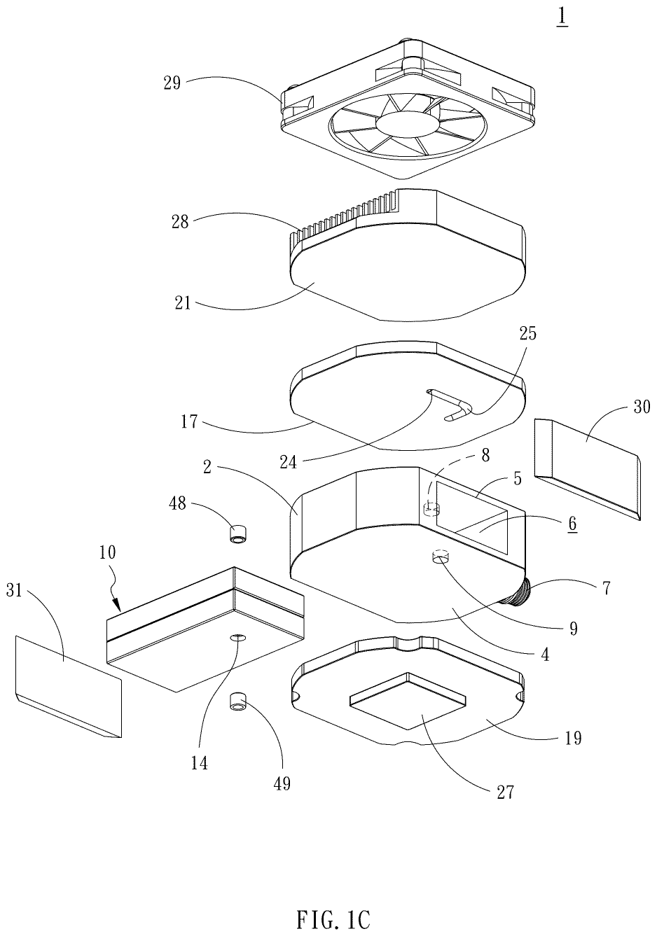

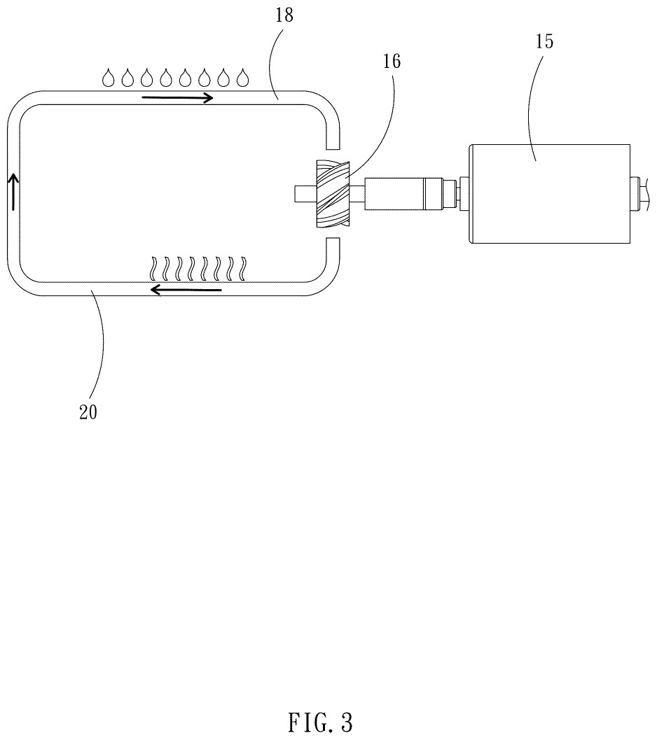

Referring to FIG. 1A to FIG. 1B, the present disclosure aims at providing a heat dissipation device 1, comprising a main body 2 having a top side 3 and a bottom side 4 arranged opposite to the top side 3. The main body 2 comprises a first penetration portion 5 passing through the main body 2, which allows two ends of the main body 2 to be in communication, with a penetration space 6 formed therein. A valve port 7 is formed on an end of the main body 2. A first through hole 8 is formed on the top side 3 and in communication with the valve port 7 and the penetration space 6. A second through hole 9 is formed on the bottom side 4 and in communication with the penetration space 6. A flow guiding device 10 is disposed in the penetration space 6, and comprises a box body 11 defining a flow guiding space 12 therein. The box body 11 has an input hole 13 formed on one side of the box body 11 at a position corresponding to the first through hole 8 and in communication with the flow guiding space 12, and an output hole 14 formed on another side of the box body 11 at a position corresponding to the second through hole 9 and in communication with the flow guiding space 12. A motor 15 is disposed in the box body 11, and a rotor 16 is accommodated in the flow guiding space 12 and rotatably connected to the motor 15, so as to drive a first fluid to flow from the input hole 13 through the flow guiding space 12 toward the output hole 14. A first flow guide plate 17 is disposed on the top side 3 of the main body 2, and a first flow guiding channel 18 is formed on one side of the first flow guide plate 17 opposite to the main body 2, with an end of the first flow guiding channel 18 being in communication with the first through hole 8 and the flow guiding space 12. A second flow guide plate 19 is disposed on the bottom side 4 of the main body 2, and a second flow guiding channel 20 is formed on one side of the second flow guide plate 19 in contact with the main body 2, while the second flow guiding channel 20 has an end in communication with the second through hole 9 and the flow guiding space 12, and the other end in communication with the other end of the first flow guiding channel 18. The first fluid is flowable in the second flow guiding channel 20 to absorb heat and vaporize. A heat exchange plate 21 is disposed on one side of the first flow guide plate 17 opposite to the main body 2 to cover the first flow guiding channel 18. The first fluid is flowable in the first flow guiding channel 18 and cooled to condense into a liquid state via the heat exchange plate 21, wherein the cooling circulation thereof is schematically shown in FIG. 3. In a preferred embodiment, the valve port 7 is used for injecting or extracting the first fluid.

Preferably, referring to 1C, the heat dissipation device 1 further comprises a heating member 27 formed on one side of the second flow guide plate 19 opposite to the main body 2. Therein, in order to create a relatively large temperature difference between the heating member 27 on the second flow guide plate 19 and the first fluid, so as to ensure that the first fluid absorbs the heat from the second flow guide plate 19 and the heating member 27 to vaporize and thereby achieve a cooling effect, the first fluid is a refrigerant either in liquid state or in a two-phase liquid-gas condition. Specifically, when the first fluid is injected from the first through hole 8 into the flow guiding space 12, the rotor 16 drives the first fluid toward the second flow guiding channel 20. When the first fluid flows to the second flow guiding channel 20 and receives the heat transmitted from the heating member 27, the first fluid vaporizes and is driven along the second penetration portion 22 toward the first flow guiding channel 18. When the vaporized first fluid flows to the first flow guiding channel 18, the heat thereof is transmitted toward the heat exchange plate 21, and the first fluid condenses back to the liquid form and then flows through the fourth through hole 24 back to the flow guiding space 12, completing a heat dissipation circulation. In a preferred embodiment, the heating member 27 is a heat source of an electronic component, preferably a computer processor, including but not limited to a CPU (Central Processing Unit) or NPU (Neural Network Processing Unit).

Preferably, when the rotor 16 rotates, in order to drive the first fluid in the first flow guiding channel 18 into the flow guiding space 12 and simultaneously drive the first fluid in the flow guiding space 12 to flow through the output hole 14 into the second flow guiding channel 20, the rotors 16 comprises a rotating shaft 46 and at least a blade 47 disposed on an outer periphery of the rotating shaft 46. It is understood that when a plurality of the blades 47 are provided, the blades 47 are arranged radially or spirally on the rotating shaft 46. Preferably, the number of the blades 47 ranges from 2 to 16, but is not limited thereto. In a preferred embodiment, in order to achieve an accurate alignment between the first through hole 8 and the input hole 13 and between the second through hole 9 and the output hole 14, so as to ensure the sealing tightness of the first fluid and preventing leakage thereof, the heat dissipation device 1 comprises a first connection pipe 48 passing through the first through hole 8 and a second connection pipe 49 passing through the second through hole 9. The first connection pipe 48 has an end in communication with the fourth through hole 24 and the other end connected to the input hole 13. The second connection pipe 49 has an end in communication with the output hole 14 and the other end connected to an end of the second flow guiding channel 20 adjacent to the second through hole 9.

Preferably, in order to communicate the first flow guiding channel 18, the second flow guiding channel 20, and the flow guiding space 12 and enhance the sealing tightness to prevent leakage of the first fluid, so as to prevent the electronic device from moisture intrusion, damage, malfunction, or short-circuiting, the heat dissipation device 1 further comprises a second penetration portion 22, a third penetration portion 23, and a fourth penetration portion 24. The second penetration portion 22 passes through the main body 2 to communicate the top side 3 and the bottom side 4, wherein an end of the second penetration portion 22, which is in contact with the top side 3, is in communication with an end of the first flow guiding channel 18 opposite to the first through hole 8, and an end of the second penetration portion 22, which is in contact with the bottom side 4, is in communication with an end of the second flow guiding channel 20 opposite to the second through hole 9. The third through hole 23 passes through the first flow guide plate 17 at a position corresponding to the second penetration portion 22, such that the second penetration portion 22 is in communication with the first flow guiding channel 18. The fourth through hole 24 passes through the first flow guide plate 17 at a position corresponding to the first through hole 8, such that the first flow guiding channel 18 is sequentially in communication with the first through hole 8 and the penetration space 6 via the fourth through hole 24.

Preferably, in order to inject or draw the first fluid, which is in either a liquid or gaseous state, into or from the first flow guiding channel 18, the flow guiding space 12 or the second flow guiding channel 20, the heat dissipation device 1 further comprises a third flow guiding channel 25 and a third penetration portion 26. The third flow guiding channel 25 is formed on one side of the first flow guide plate 17 opposite to the first flow guiding channel 18, and an end of the third flow guiding channel 25 is in communication with the first through hole 8 and the fourth through hole 24. The third penetration portion 26 is formed on the main body 2, wherein an end of the third penetration portion 26 is in communication with the valve port 7, and the other end of the third penetration portion 2 is in communication with the top side 3 of the main body 2 and also in communication with the other end of the third flow guiding channel 25 opposite to the first through hole 8.

Preferably, after the first fluid passes the second flow guiding channel 20 and absorbs the heat transmitted from the heat member 27 or the electronic component to the second flow guide plate 19, in order to allow the heat exchange plate 21 to efficiently transfer the heat in the first fluid when the first fluid continues to flow into the first flow guiding channel 18 on the first flow guide plate 17, and subsequently allow the cooled first fluid to flow back to the flow guiding space 12 to repeat the heating and cooling circulation. As shown in FIG. 1C, the heat dissipation device 1 further comprises a plurality of first fins 28 disposed on one side of the heat exchange plate 21 opposite to the main body 2 and arranged at equal intervals. It is understood that the first fins 28 are able to improve the contact area between the heat exchange plate 21 and air, so as to enhance the cooling efficiency of the first fluid. In a preferred embodiment, to enhance the air convection and thereby increase the heat exchange efficiency between the heat exchange plate 21 and the first fluid, the heat dissipation device 1 further comprises a first fan 29 disposed on the side of the heat exchange plate 21 opposite to the main body 2. In a preferred embodiment, the heat dissipation device 1 further comprises a first sealing cover 30 disposed on the main body 2 corresponding to an end of the penetration space 6, so as to cover said end of the penetration space 6, and a second sealing cover 31 disposed on the main body 2 corresponding to the other end of the penetration space 6, so as to cover said other end of the penetration space 6.

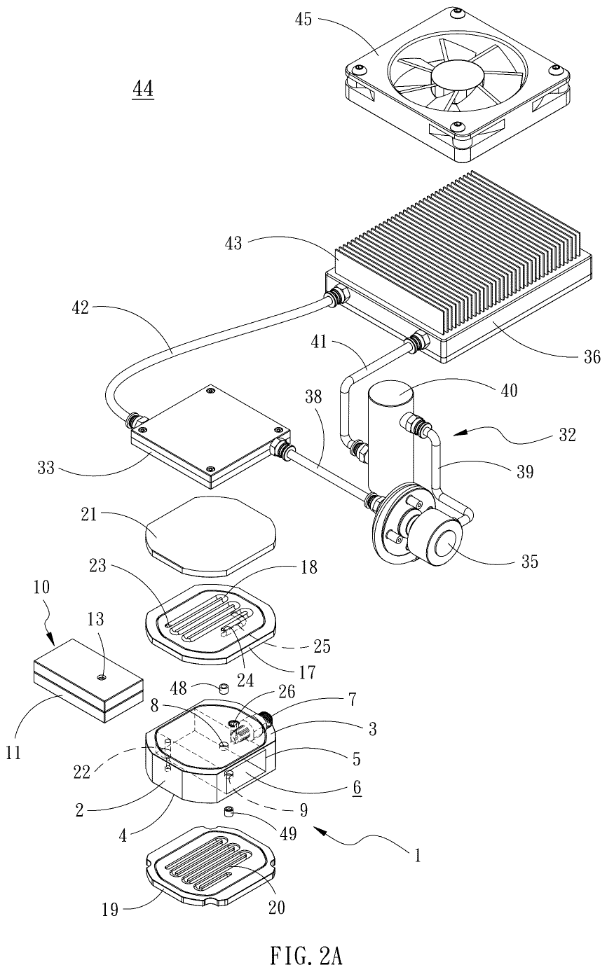

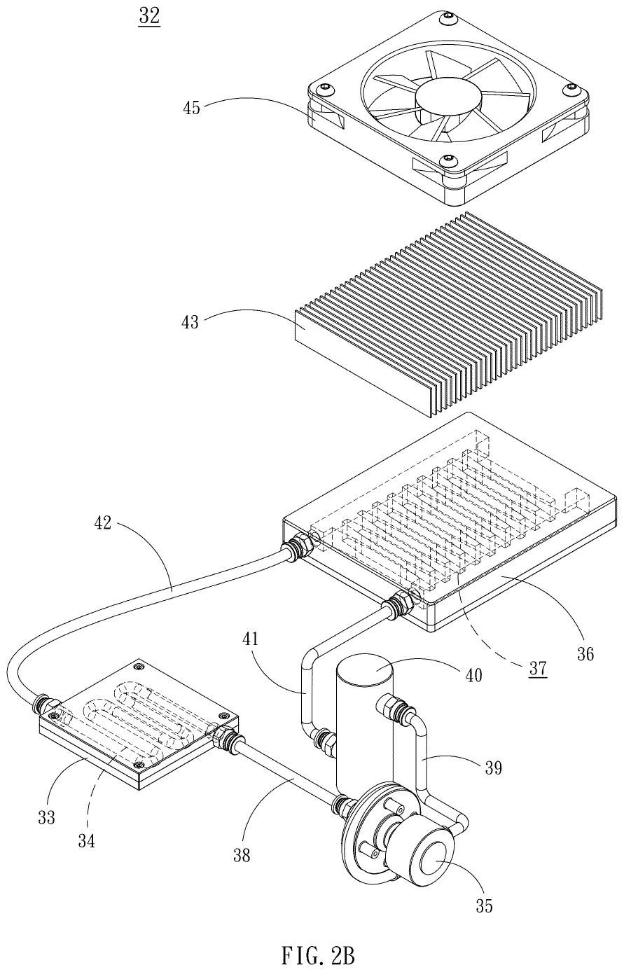

Referring to FIG. 2A to FIG. 2B, the present disclosure aims at providing a heat dissipation system 44 comprising a heat dissipation device 1, which comprises a main body 2 having a top side 3 and a bottom side 4 arranged opposite to the top side 3. The main body 2 comprises a first penetration portion 5 passing through the main body 2, which allows two ends of the main body 2 to be in communication, with a penetration space 6 formed therein. A valve port 7 is formed on an end of the main body 2. A first through hole 8 is formed on the top side 3 and in communication with the valve port 7 and the penetration space 6. A second through hole 9 is formed on the bottom side 4 and in communication with the penetration space 6. A flow guiding device 10 is disposed in the penetration space 6, and comprises a box body 11 (also referring to FIG. 1B) defining a flow guiding space 12 therein. The box body 11 has an input hole 13 formed on one side of the box body 11 at a position corresponding to the first through hole 8 and in communication with the flow guiding space 12, and an output hole 14 formed on another side of the box body 11 at a position corresponding to the second through hole 9 and in communication with the flow guiding space 12. A motor 15 is disposed in the box body 11, and a rotor 16 is accommodated in the flow guiding space 12 and rotatably connected to the motor 15, so as to drive a first fluid to flow from the input hole 13 through the flow guiding space 12 toward the output hole 14. A firs t flow guide plate 17 is disposed on the top side 3 of the main body 2, and a first flow guiding channel 18 is formed on one side of the first flow guide plate 17 opposite to the main body 2, with an end of the first flow guiding channel 18 being in communication with the first through hole 8 and the flow guiding space 12. A second flow guide plate 19 is disposed on the bottom side 4 of the main body 2, and a second flow guiding channel 20 is formed on one side of the second flow guide plate 19 in contact with the main body 2, while the second flow guiding channel 20 has an end in communication with the second through hole 9 and the flow guiding space 12, and the other end in communication with the other end of the first flow guiding channel 18. The first fluid is flowable in the second flow guiding channel 20 to absorb heat and vaporize. A heat exchange plate 21 is disposed on one side of the first flow guide plate 17 opposite to the main body 2 to cover the first flow guiding channel 18. The first fluid is flowable in the first flow guiding channel 18 and cooled to condense into a liquid state via the heat exchange plate 21. Also, a heat exchange device 32 is included, comprising a first heat exchange box 33, a pump 35, and a second heat exchange box 36. The first heat exchange box 33 is disposed on one side of the heat exchange plate 21 opposite to the first flow guide plate 17, with a heat absorbing channel 34 formed in the first exchange box 33. The pump 35 is in communication with an end of the heat absorbing channel 34. The second heat exchange box 36 comprises a cooling channel 37 therein. The cooling channel 37 has an end connected to the pump 35 and the other end 37 in communication with the other end of the heat absorbing channel 34, allowing the pump 35 to pressurize a second fluid, whereby the second fluid circulates within the heat absorbing channel 34 and the cooling channel 37.

Preferably, in order to guide the heated second fluid away from the heat exchange plate 21 first to be cooled and thereby prevent the excessive heat concentration on the heat exchange plate 21, the heat dissipation system 44 further comprises a first water pipe 38, a second water pipe 39, a buffering device 40, a third water pipe 41, and a fourth water pipe 42. The first water pipe 38 has two ends connected to an end of the heat absorbing channel 34 and the pump 35, respectively. The second water pipe 39 has an end connected to the pump 35. The buffering device 40 is connected to the other end of the second water pipe 39 opposite to the pump 35. The third water pipe 41 has two ends connected to the buffering device 40 and an end of the cooling channel 37, respectively. The fourth water pipe 42 has two ends connected to the other end of the cooling channel 37 opposite to the third water pipe 41 and the other end of the heat absorbing channel 34 opposite to the first water pipe 38. Therein, the second fluid sequentially flows from the heat absorbing channel 34 through the first water pipe 38, the pump 35, the second water pipe 39, the buffering device 40, the third water pipe 41, the cooling channel 37, and the fourth water pipe 42, and then returns to the heat absorbing channel 34. In a preferred embodiment, the buffering device 40 is configured to store the second fluid, such as a coolant, and serves as a buffer tank for the coolant; however, it is not limited thereto.

Preferably, in order to enhance the cooling efficiency of the second fluid, the heat dissipation system 44 further comprises a plurality of second fins 43 disposed on one side of the second heat exchange box 36 and arranged at equal intervals or a second fan 45 disposed on one side of the second heat exchange box 36. In a preferred embodiment, the plurality of second fins 43 are formed on one side of the second heat exchange box 36 first, and the second fan 45 is disposed on one side of the second fins 43 opposite to the second heat exchange box 36, so as to significantly enhance the heat exchange effect between the second heat exchange box 36 and the second fluid. In a preferred embodiment, the second fluid includes, for example but not limited to, water, propylene glycol, or general coolant, either in liquid state or in a two-phase liquid-gas condition; however, it is not limited thereto.

Referring to FIG. 1A, FIG. 1B, FIG. 2A, and FIG. 3, with the foregoing configuration, the present disclosure does not require a compressor for refrigerant compression. Instead, by merely rotating the motor 15 rotor 16 having blades 47 within the flow guiding space 12, the first fluid (e.g., the refrigerant) is propelled in a forward direction from the flow guiding space 12 sequentially through the output hole 14 and the second through hole 9 into the second flow guiding channel 20, so as to absorb heat to vaporize first. Then, the vaporized refrigerant flows from the second flow guiding channel 20 through the second penetration portion 22 and the third through hole 23 into the first flow guiding channel 18, where the refrigerant releases the heat to condense back to the liquid state. Finally, the condensed refrigerant flows sequentially from the first flow guiding channel 18 through the fourth through hole 24, the first through hole 8, and the input hole 13, and returns back to the flow guiding space 12, forming a continuous circulation loop, thereby achieving a stable and efficient heat exchange operation with minimal energy consumption. Also, components of the main body 2 are allowed to be assembled with an airtight structure, so as to provide an excellent sealing performance for the main body 2, thereby preventing shaking of the flow guiding device 10 and ensuring the sealing tightness of the first fluid, avoiding leakage thereof outside the main body 2, and ensuring the safety of electronic device when disposed on the second flow guide plate 19, so as to prevent the electronic device from being short circuited or damaged. Furthermore, in the present disclosure, a heat exchange device 32 is disposed on the heat exchange plate 21 to further transfer heat from the heat exchange plate 21 to a remote location, so as to prevent excessive heat accumulation at the position of the heat exchange plate 21, thereby ensuring that the first fluid flowing back to the flow guiding space 12 has been adequately cooled, allowing the next round of circulation of heat absorption and vaporization followed by heat dissipation and condensation operations. In summary, the present disclosure is applied to cool high-power computer processors, thereby allowing the processors to operate at high power without performance degradation.

What is claimed is:

1. A heat dissipation device, comprising:
a main body having a top side and a bottom side arranged opposite to the top side, the main body further comprising:
a first penetration portion passing through the main body to communicate two ends of the main body and form a penetration space;
a valve port formed on an end of the main body;
a first through hole formed on the top side and in communication with the valve port and the penetration space;
a second through hole formed on the bottom side and in communication with the penetration space;
a flow guiding device disposed in the penetration space, comprising:
a box body defining a flow guiding space therein and comprising:
an input hole formed on one side of the box body at a position corresponding to the first through hole and in communication with the flow guiding space; and
an output hole formed on another side of the box body at a position corresponding to the second through hole and in communication with the flow guiding space;
a motor disposed in the box body; and
a rotor accommodated in the flow guiding space and rotatably connected to the motor, so as to drive a first fluid to flow from the input hole through the flow guiding space toward the output hole;
a first flow guide plate disposed on the top side of the main body, a first flow guiding channel formed on one side of the first flow guide plate opposite to the main body, and an end of the first flow guiding channel being in communication with the first through hole;
a second flow guide plate disposed on the bottom side of the main body, a second flow guiding channel formed on one side of the second flow guide plate in contact with the main body, the second flow guiding channel having an end in communication with the second through hole and another end in communication with another end of the first flow guiding channel, the first fluid being flowable in the second flow guiding channel to absorb heat and vaporize; and
a heat exchange plate disposed on one side of the first flow guide plate opposite to the main body to cover the first flow guiding channel, the first fluid being flowable in the first flow guiding channel and cooled to condense into a liquid state via the heat exchange plate.

2. The heat dissipation device of claim 1, further comprising:
a second penetration portion passing through the main body to communicate the top side and the bottom side, wherein an end of the second penetration portion, in contact with the top side, is in communication with an end of the first flow guiding channel opposite to the first through hole, and another end of the second penetration portion, in contact with the bottom side, is in communication with an end of the second flow guiding channel opposite to the second through hole;
a third through hole passing through the first flow guide plate at a position corresponding to the second penetration portion to communicate the second penetration portion with the first flow guiding channel; and
a fourth through hole passing through the first flow guide plate at a position corresponding to the first through hole to sequentially communicate the first flow guiding channel with the first through hole and the penetration space via the fourth through hole.

3. The heat dissipation device of claim 1, wherein the rotor comprises:
a rotating shaft; and
at least a blade disposed on an outer periphery of the rotating shaft.

4. The heat dissipation device of claim 2, further comprising:
a first connection pipe passing through the first through hole, the first connection pipe having an end connected to the fourth through hole and another end connected to the input hole; and
a second connection pipe passing through the second through hole, the second connection pipe having an end connected to the output hole and another end connected to an end of the second flow guiding channel adjacent to the second through hole.

5. The heat dissipation device of claim 2, further comprising:
a third flow guiding channel formed on one side of the first flow guide plate opposite to the first flow guiding channel, an end of the third flow guiding channel being in communication with the first through hole and the fourth through hole; and
a third penetration portion formed on the main body, an end of the third penetration portion being in communication with the valve port, and another end of the third penetration portion being in communication with the top side of the main body and also in communication with another end of the third flow guiding channel opposite to the first through hole.

6. The heat dissipation device of claim 1, further comprising:
a heating member formed on one side of the second flow guide plate opposite to the main body;
a plurality of first fins disposed on one side of the heat exchange plate opposite to the main body at equal intervals; or
a first fan disposed on the side of the heat exchange plate opposite to the main body.

7. The heat dissipation device of claim 1, further comprising:
a first sealing cover disposed on the main body corresponding to an end of the penetration space, so as to cover said end of the penetration space; and
a second sealing cover disposed on the main body corresponding to another end of the penetration space, so as to cover said other end of the penetration space.

8. A heat dissipation system, comprising:
a heat dissipation device, comprising:
a main body having a top side and a bottom side arranged opposite to the top side, the main body further comprising:
a first penetration portion passing through the main body to communicate two ends of the main body and form a penetration space;
a valve port formed on an end of the main body;
a first through hole formed on the top side and in communication with the valve port and the penetration space;
a second through hole formed on the bottom side and in communication with the penetration space;
a flow guiding device disposed in the penetration space, comprising:
a box body defining a flow guiding space therein and comprising:
an input hole formed on one side of the box body at a position corresponding to the first through hole and in communication with the flow guiding space; and
an output hole formed on another side of the box body at a position corresponding to the second through hole and in communication with the flow guiding space;
a motor disposed in the box body; and
a rotor accommodated in the flow guiding space and rotatably connected to the motor, so as to drive a first fluid to flow from the input hole through the flow guiding space toward the output hole;
a first flow guide plate disposed on the top side of the main body, a first flow guiding channel formed on one side of the first flow guide plate opposite to the main body, and an end of the first flow guiding channel being in communication with the first through hole;
a second flow guide plate disposed on the bottom side of the main body, a second flow guiding channel formed on one side of the second flow guide plate in contact with the main body, the second flow guiding channel having an end in communication with the second through hole and another end in communication with another end of the first flow guiding channel, the first fluid being flowable in the second flow guiding channel to absorb heat and vaporize; and
a heat exchange plate disposed on one side of the first flow guide plate opposite to the main body to cover the first flow guiding channel, the first fluid being flowable in the first flow guiding channel and cooled to condense into a liquid state via the heat exchange plate; and
a heat exchange device, comprising:
a first heat exchange box disposed on one side of the heat exchange plate opposite to the first flow guide plate, with a heat absorbing channel formed in the first exchange box;
a pump in communication with an end of the heat absorbing channel; and
a second heat exchange box comprising a cooling channel therein, the cooling channel having an end connected to the pump and another end in communication with another end of the heat absorbing channel, allowing the pump to pressurize a second fluid, whereby the second fluid circulates within the heat absorbing channel and the cooling channel.

9. The heat dissipation system of claim 8, further comprising:
a first water pipe having two ends connected to an end of the heat absorbing channel and to the pump, respectively;
a second water pipe having an end connected to the pump;
a buffering device connected to another end of the second water pipe opposite to the pump;
a third water pipe having two ends connected to the buffering device and to an end of the cooling channel, respectively; and
a fourth water pipe having two ends connected to another end of the cooling channel opposite to the third water pipe and to another end of the heat absorbing channel opposite to the first water pipe, wherein the second fluid sequentially flows from the heat absorbing channel through the first water pipe, the pump, the second water pipe, the buffering device, the third water pipe, the cooling channel, and the fourth water pipe, and returns to the heat absorbing channel.

10. The heat dissipation system of claim 8, further comprising:
a plurality of second fins disposed on one side of the second heat exchange box at equal intervals; or
a second fan disposed on one side of the second heat exchange box.

11. A heat dissipation device, comprising:
a main body having a top side and a bottom side arranged opposite to the top side;
a flow guiding device disposed in the main body and comprising:
a box body defining a flow guiding space therein;
a motor disposed in the box body; and
a rotor accommodated in the flow guiding space and rotatably connected to the motor, so as to drive a first fluid to flow;
a first flow guide plate disposed on the top side of the main body, a first flow guiding channel formed on one side of the first flow guide plate opposite to the main body, and an end of the first flow guiding channel being in communication with the flow guiding space;
a second flow guide plate disposed on the bottom side of the main body, a second flow guiding channel formed on one side of the second flow guide plate in contact with the main body, the second flow guiding channel having an end in communication with the flow guiding space and another end in communication with another end of the first flow guiding channel, the first fluid being flowable in the second flow guiding channel to absorb heat and vaporize; and
a heat exchange plate disposed on one side of the first flow guide plate opposite to the main body to cover the first flow guiding channel, the first fluid being flowable in the first flow guiding channel and cooled to condense into a liquid state via the heat exchange plate.
